(19) United States
(12) Patent Application Publication
(10) Pub. No.: US 2017/0125293 A1
(43) Pub. Date: May 4, 2017

(54) SUBSTRATE ARRAY FOR PACKAGING INTEGRATED CIRCUITS

(71) Applicant: FREESCALE SEMICONDUCTOR, INC., Austin, TX (US)

(72) Inventors: ZHIJIE WANG, Tianjin (CN); ZHIGANG BAI, Tianjin (CN); JIYONG NIU, Tianjin (CN)

(21) Appl. No.: 15/256,573

(22) Filed: Sep. 4, 2016

(30) Foreign Application Priority Data
Oct. 30, 2015 (CN) 201510943630.7

(51) Int. Cl. H01L 21/78; H01L 23/31; H01L 21/48; H01L 23/00; H01L 21/56; H01L 21/52; H01L 21/66; H01L 23/492

(52) U.S. Cl. CPC H01L 21/78; H01L 22/10; H01L 23/3114; H01L 23/3178; H01L 23/492; H01L 24/09; H01L 21/56; H01L 21/52; H01L 21/4875; H01L 2224/0912

(57) ABSTRACT

A method for packaging integrated circuits includes providing a substrate array having (i) multiple individual substrates, each of which has bottom contact pads and corresponding conductive traces and (ii) plating busses located between adjoining ones of the substrates and electrically connected to the bottom contact pads by way of the traces. The method further includes (i) forming slots in the substrate array by removing portions of the plating busses connected to the traces while leaving corner attachment zones connecting adjacent individual substrates, (ii) attaching and electrically connecting dies to the substrates, (iii) encapsulating the dies, (iv) electrically and functionally testing the assemblies, and then, after the testing, (v) singulating the assemblies, which yields individual IC devices corresponding to the individual substrates.

### BACKGROUND

The present invention relates to integrated circuit (IC) packaging and, more particularly, to substrates for packaging integrated circuits.

FIG. 1A is a bottom view of a conventional substrate array 100 comprising eighteen individual substrates 101 and a perimeter zone 102. FIG. 1B is an enlargement of a detail area 103 of FIG. 1A, which comprises four of the substrates 101. FIG. 1C is an enlarged side cross-sectional view of a sub-assembly 104 comprising one of the substrates 101 of FIG. 1B along cut line Z-Z, showing the sub-assembly 104 after die attaching, wire bonding, and encapsulation steps, but before singulation.

The substrate array 100 may be used in the packaging of eighteen corresponding ball grid array (BGA) ICs. The substrate array 100 comprises a substrate material 105, which may be, for example, a bismaleimide-triazine (BT) resin. The substrate material 105 provides structure for holding in place the below-described components of the substrate array 100. Each individual substrate 101 comprises a plurality (sixty-four are shown) of metal bottom contact pads 106, each connected by a corresponding conductive metal trace 107 to a nearby plating bus 108. The plating busses 108 border each of the individual substrates 101. In other words, each individual substrate 101 is separated from the adjoining individual substrates 101 and/or the perimeter zone 102 by a plating bus 108. Each individual substrate 101 also comprises top contact pads 109 and vias and/or traces (not shown) within the substrate material 105, which interconnect the top contact pads 109 and some of the bottom contact pads 106.

The top contact pads 109, the bottom contact pads 106, and the interconnecting vias/traces typically comprise copper. During the manufacturing of the substrate array 100, the bottom contact pads 106 may be electroplated with, for example, nickel and/or gold (not shown). The plating busses 108 are used to provide electricity to the bottom contact pads 106 for the electroplating process. After electroplating, dies 110 are attached, on the top side, to corresponding individual substrates 101 and are electrically connected to the top contact pads 109 with corresponding bond wires 111. Following the wire bonding step, the top side of the substrate array 100—including the dies 110 and the bond wires 111—is encapsulated in an encapsulant 113, which typically comprises an epoxy molding compound.

Following encapsulation, singulation is performed, where a saw is used to cut apart the sub-assemblies 104 of the substrate array 100. The saw grinds away the parts of the sub-assemblies 104 outside of cut lines 112, shown in FIG. 1C. The singulation removes the plating busses 108, as well as the adjoining ends of the conductive (electroplated) traces 107. Note that, prior to singulation, the bottom contacts pads 106 are shorted together by the plating busses 108, but afterwards, they are no longer shorted together by the plating busses 108 (although select subsets of the bottom contact pads 106 may be shorted together by other components of the sub-assemblies 104, e.g., by the traces and/or vias within the individual substrate 101). Consequently, certain electrical and/or functional tests can be performed only after singulation, when the bottom contacts pads 106 are no longer externally shorted together.

As is appreciated by a person of ordinary skill in the art, bulk testing of the entire substrate array 100, also known as strip testing, is more efficient than individual testing of singulated sub-assemblies 104. Strip testing of the die-attached, wire-bonded, and encapsulated substrate array 100 may be done by performing a half-cut step, after encapsulation, which grinds away the plating busses 108 and the corresponding substrate material 105 up to the encapsulant 113. However, this structurally weakens the substrate array 100, which makes handling of the substrate array 100 more difficult and increases the likelihood of damage to its components.

### BRIEF DESCRIPTION OF THE DRAWINGS

Aspects, features, and advantages of the invention will become more fully apparent from the following detailed description, the appended claims, and the accompanying drawings in which like reference numerals identify similar or identical elements. Elements in the figures are not drawn to scale.

FIG. 1A is a bottom view of a conventional substrate array;

FIG. 1B is an enlargement of a detail area of FIG. 1A;

FIG. 1C is an enlarged side cross-sectional view of a sub-assembly comprising an individual substrate of FIG. 1B;

FIG. 2A is a bottom view of a substrate array in accordance with one embodiment of the present invention;

FIG. 2B is an enlargement of a detail area of FIG. 2A;

FIG. 2C is an enlarged side cross-sectional view of a portion of FIG. 2B;

FIG. 3A is a bottom view of an assembly comprising the substrate array of FIG. 2A;

FIG. 3B is an enlargement of a detail area of FIG. 3A;

FIG. 3C is an enlarged side cross-sectional view of a portion of FIG. 3B;

FIG. 4A is a bottom view of an assembly comprising the assembly of FIG. 3A;

FIG. 4B is an enlargement of a detail area of FIG. 4A;

FIG. 4C is an enlarged side cross-sectional view of a portion of FIG. 4B;

FIG. 5A is a bottom view of an assembly comprising the assembly of FIG. 4A;

FIG. 5B is an enlargement of a detail area of FIG. 5A;

FIG. 5C is an enlarged side cross-sectional view of a portion of FIG. 5B;

FIG. 6A is a bottom view of a singulated IC device corresponding to a sub-assembly of FIG. 5B; and

FIG. 6B is an enlarged side cross-sectional view of the IC device of FIG. 6A.

### DETAILED DESCRIPTION

Detailed illustrative embodiments of the present invention are disclosed herein. However, specific structural and functional details disclosed herein are merely representative for purposes of describing example embodiments of the present invention. Embodiments of the present invention may be embodied in many alternative forms and should not be construed as limited to only the embodiments set forth herein. Further, the terminology used herein is for the purpose of describing particular embodiments only and is not intended to be limiting of example embodiments of the invention.

As used herein, the singular forms “a,” “an,” and “the,” are intended to include the plural forms as well, unless the context clearly indicates otherwise. It further will be understood that the terms “comprises,” “comprising,” “has,” “having,” “includes,” and/or “including” specify the presence of stated features, steps, or components, but do not preclude the presence or addition of one or more other features, steps, or components. It also should be noted that, in some alternative implementations, the functions/acts noted may occur out of the order noted in the figures.

In one embodiment, the present invention provides a method for packaging integrated circuit (IC) devices, including (i) providing a substrate array, wherein the substrate array comprises a top side, a bottom side, a plurality of individual substrates, wherein each individual substrate comprises a plurality of bottom contact pads and corresponding conductive traces on the bottom side, and plating busses on the bottom side between adjoining substrates, and that are electrically connected to the bottom contact pads by way of the corresponding traces, and (ii) forming slots in the substrate array by removing portions of the plating busses connected to the traces while leaving corner attachment zones connecting adjacent substrates. In one embodiment, after an electroplating step and before an encapsulation step, slots are cut into the substrate array to remove portions of the plating busses sufficient to open shorts between the bottom contact pads. During encapsulation, the slots are filled with encapsulant, which provides structural strength to the substrate array during strip testing.

In another embodiment, the present invention provides a substrate array having a top side and a bottom side, where the substrate array comprises an array of adjacent individual substrates. Each substrate comprises a plurality of bottom contact pads and corresponding conductive traces on the bottom side. The substrates are separated from adjacent substrates by slots formed by removing a corresponding portion of a plating bus on the bottom side, the portion having been previously connected to the conductive traces, The substrates are connected to one or more adjacent substrates by corner attachment zones comprising remains of the plating busses.

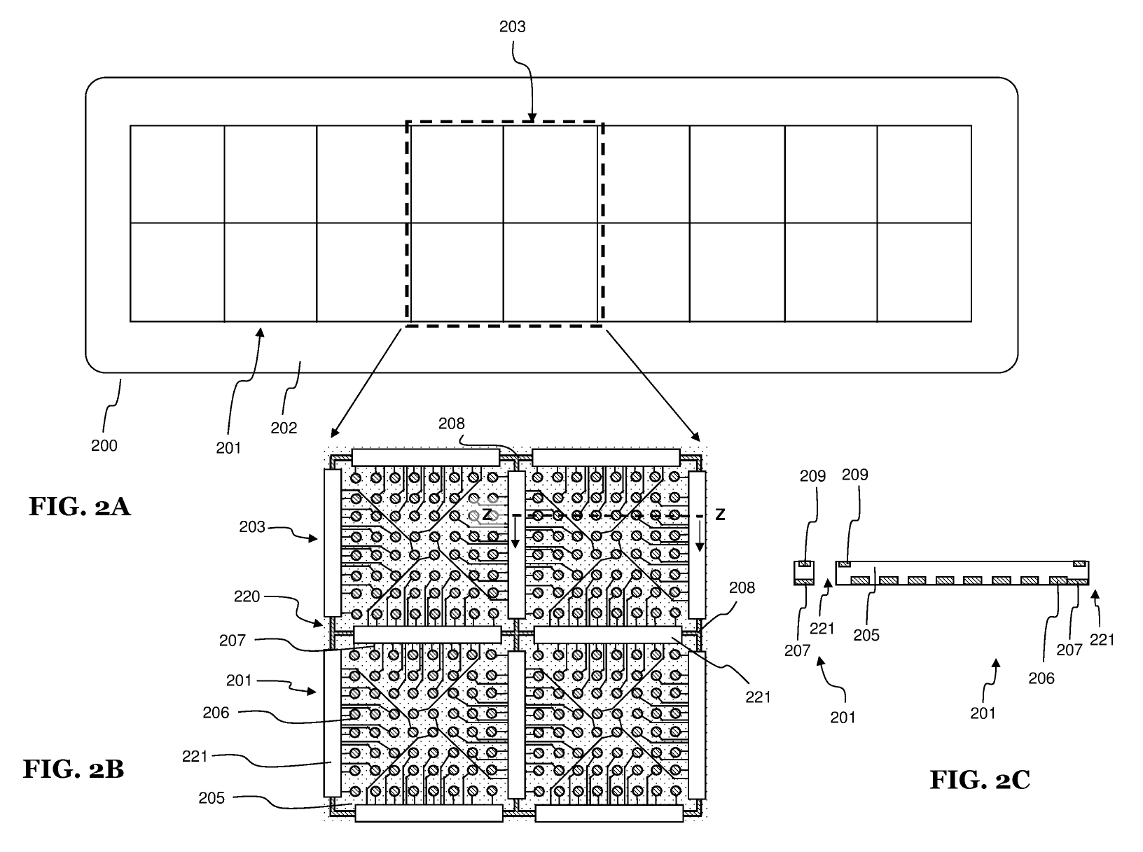

Referring now to FIGS. 2A-2C, FIG. 2A is a bottom view of a substrate array 200, which comprises a plurality (eighteen shown) individual substrates 201 and a perimeter zone 202, in accordance with one embodiment of the present invention. FIG. 2B is an enlargement of a detail area 203 of FIG. 2A, which comprises four of the substrates 201. FIG. 2C is an enlarged side cross-sectional view along cut line Z-Z of FIG. 2B, which shows a cross-section of an individual substrate 201 as well as part of an adjacent substrate 201.

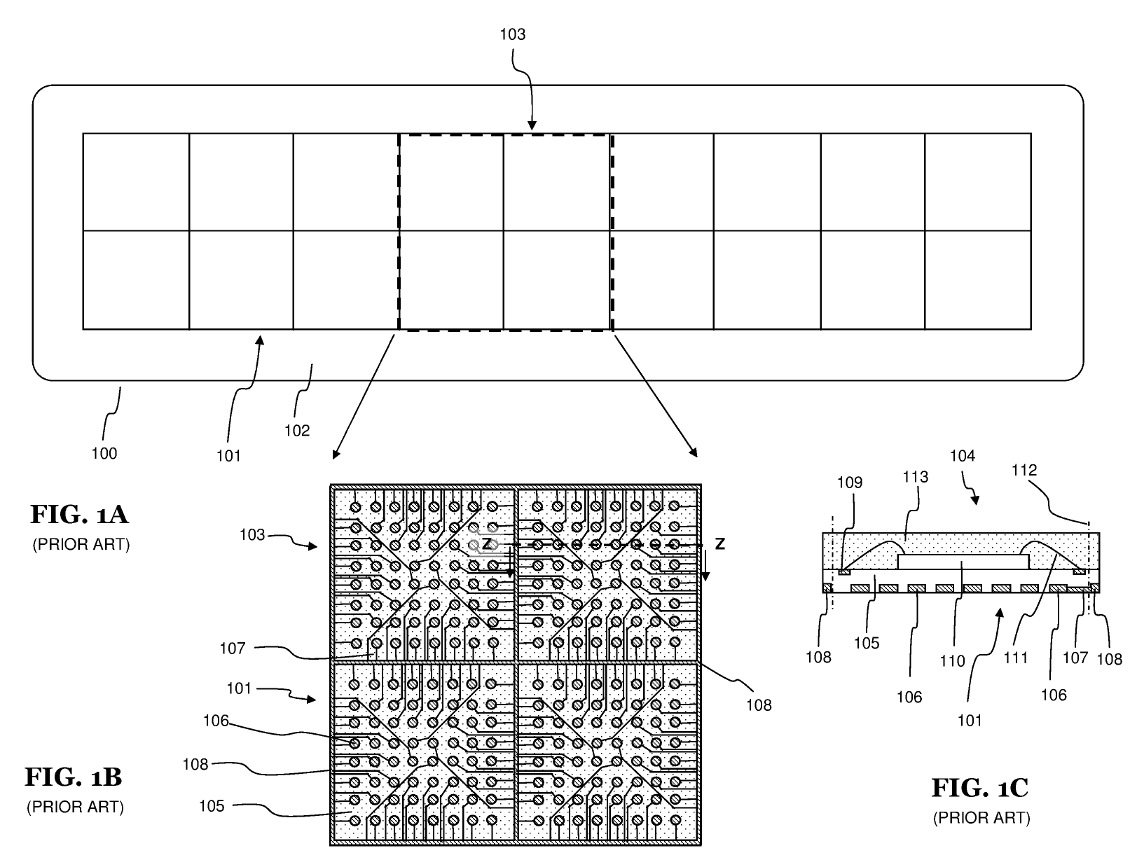

Components of the substrate array 200 that are substantially similar to corresponding components of the conventional substrate array 100 of FIG. 1A are similarly labeled, but with a different prefix. For example, the substrates 201 are formed of substrate material 205, which is the same as the substrate material 105 shown in FIGS. 1B and 1C.

The substrate array 200 has slots 221, which are elongated openings bordering the individual substrates 201. The slots 221 may be formed by, for example, punching, laser cutting, or sawing the substrate array 200 following electroplating of the substrate array 200. The slot forming removes the segments of plating busses 208 that were used to short together bottom contact pads 206 for the electroplating process, as well as adjacent portions of conductive traces 207. Hence, the slot-forming electrically isolates both (i) adjacent individual substrates 201 from each other and (ii) the bottom contact pads 206 from each other. This will allow the performance of functional electrical tests following the below-described die attachment and electrical connection, which conventionally would have required device singulation first.

Note that the slot-forming process leaves in place corner-attachment zones 220, which connect the corners of adjacent substrates 201 and which have remnants of the plating busses 208. Also note that, during the electroplating process—i.e., prior to the slot forming—top contact pads 209 along with the bottom contact pads 206 may also receive electricity from the plating busses 208 by way of the via/traces (not shown) in the substrate material 205. Alternatively, the top contact pads 209 may be connected by top-layer traces (not shown) to top-layer plating busses (not shown). The slot-forming process would also remove segments of these top-layer traces—similar to the above-described segment removal for the plating busses 208—to open the top-layer shorts between the top contact pads 209. Following the slot-forming step, corresponding dies are attached and electrically connected to the individual substrates 201, as described below.

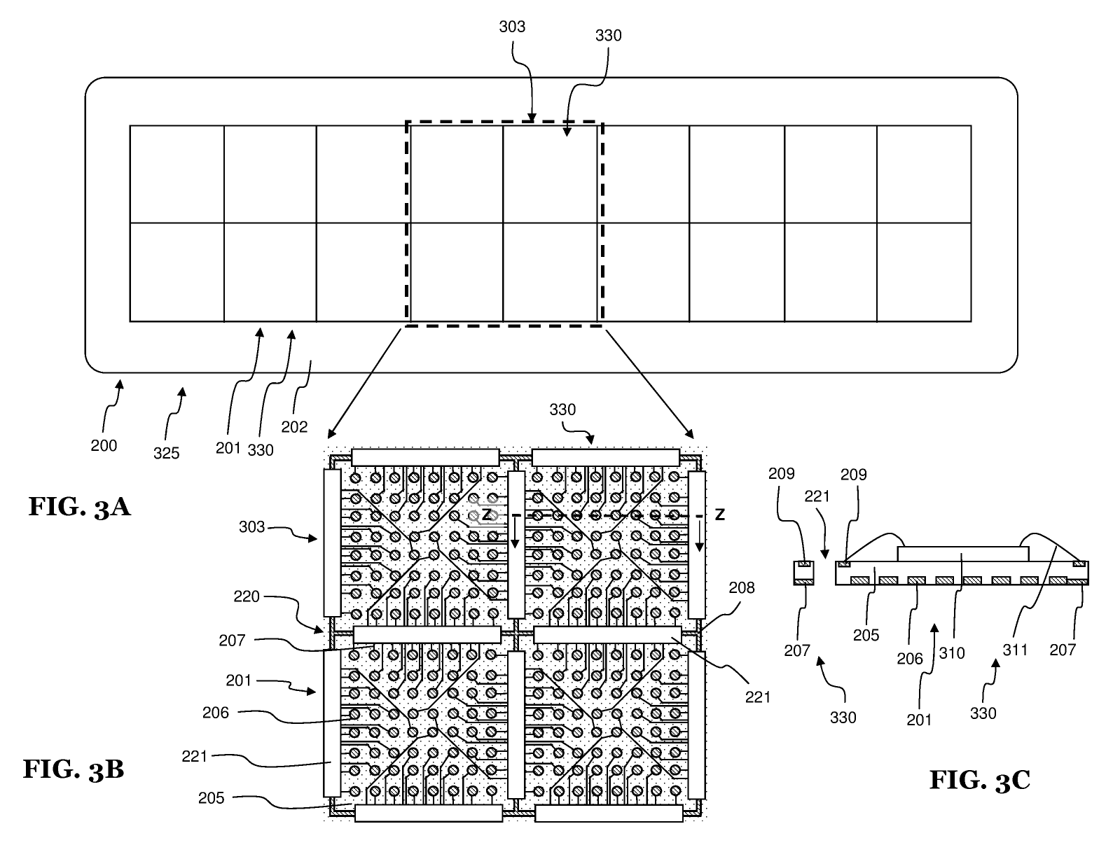

FIG. 3A is a bottom view of an assembly 325, which comprises the substrate array 200 of FIG. 2A, following the attachment and electrical connection to the top sides of the individual substrates 201 of (eighteen) corresponding semiconductor dies 310. FIG. 3B is an enlargement of a detail area 303 of FIG. 3A. FIG. 3C is an enlarged side cross-sectional view along cut line Z-Z of FIG. 3B, which shows a cross section of a sub-assembly 330 as well as part of an adjacent sub-assembly 330, where each sub-assembly 330 comprises a corresponding individual substrate 201.

The die 310 may be attached to the corresponding substrate 201 using a suitable die attach material (not shown). The die 310 is then electrically connected to the corresponding substrate 201 with bond wires 311, which connect die contact pads (not shown) on an active surface of the die 310 to corresponding top contact pads 209. Following the die attachment and wire bonding, a removable tape is applied to the bottoms of the slots 221, as described below, in order to control the flow of encapsulant in a subsequent encapsulation step.

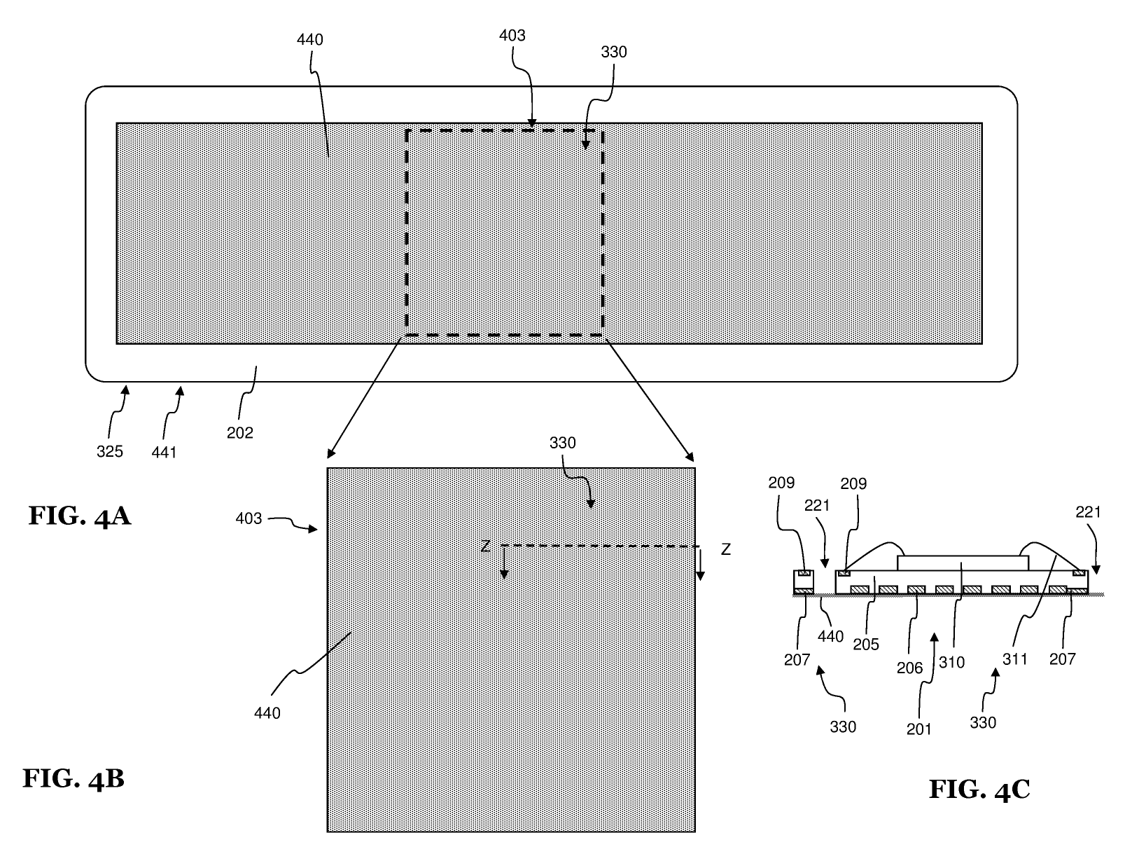

FIG. 4A is a bottom view of an assembly 441, which comprises the assembly 325 of FIG. 3A, following the attachment of a removable tape 440. FIG. 4B is an enlargement of a detail area 403 of FIG. 4A. FIG. 4C is an enlarged side cross-sectional view along cut line Z-Z of FIG. 4B, which shows a cross section of a sub-assembly 330 as well as part of an adjacent sub-assembly 330.

The tape 440 may be a pressure-sensitive adhesive tape with an acrylic core, as such are known by those of skill in the art of IC assembly. The tape 440 is used to prevent leakage onto the bottom of the substrate array 200 of a below-described encapsulant, used in a subsequent encapsulation step.

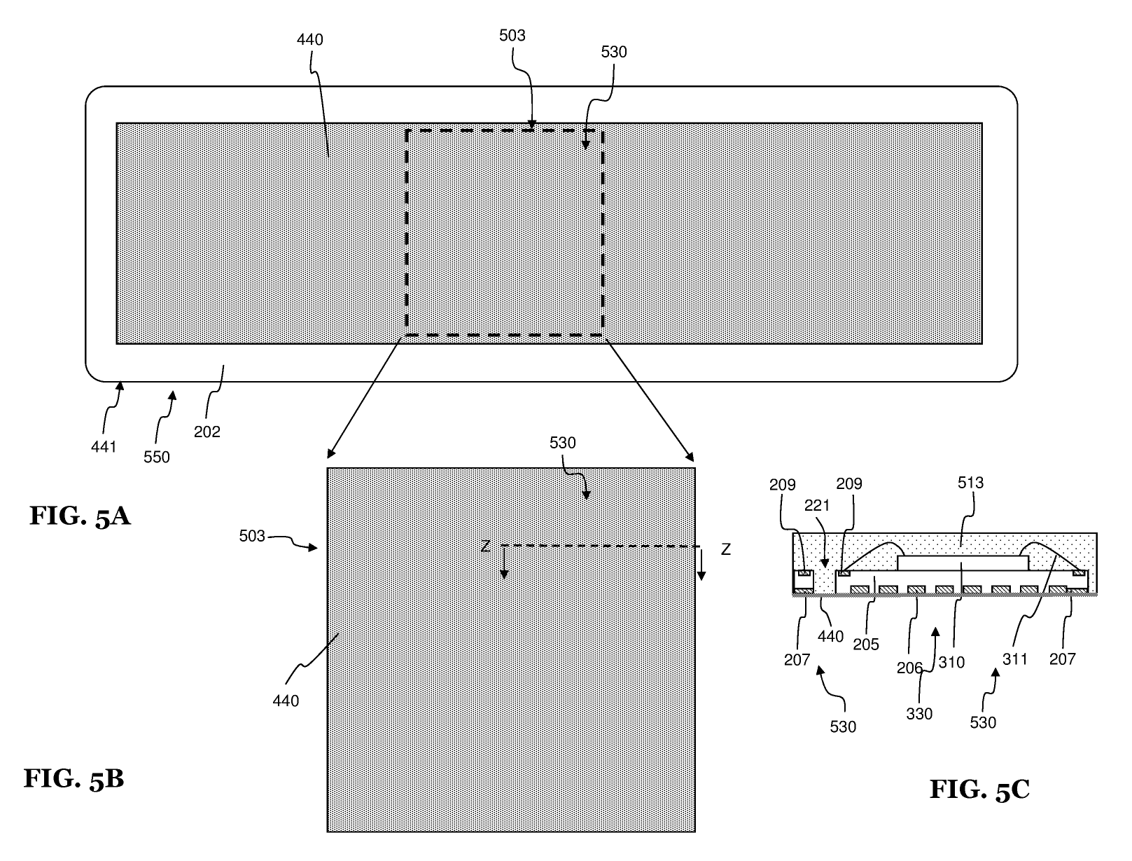

FIG. 5A is a bottom view of an assembly 550, which comprises the assembly 441 of FIG. 4A, following encapsulation of the assembly 441. FIG. 5B is an enlargement of a detail area 503 of FIG. 5A, which comprises four sub-assemblies 530. FIG. 5C is an enlarged side cross-sectional view along cut line Z-Z of FIG. 5B, which shows a cross section of the sub-assembly 530 as well as part of an adjacent sub-assembly 530, where each sub-assembly 530 comprises a corresponding sub-assembly 330 of FIG. 4C.

In the encapsulation of the assembly 441, an encapsulant 513, e.g., an epoxy molding compound, is applied to encapsulate the assembly 441, including the sub-assemblies 330, which include corresponding individual substrates 201, attached dies 310, and bond wires 311. Note that the encapsulant 513 fills in the spaces of the slots 221 in the substrate array 200. This provides enhanced structural support to the assembly 550.

Following the encapsulation step, electrical tests are performed on the sub-assemblies 530 of the assembly 550 using devices capable of simultaneously testing all of the sub-assemblies 530. This allows for faster and more-efficient testing of the sub-assemblies 530. The electrical tests may include, for example, functional tests—testing the operation of the die—and open/short tests—testing proper component interconnections.

Note that, aside from providing structural support and supporting the electrical isolation of both (i) adjacent sub-assemblies 530 from each other and (ii) the bottom contact pads 206 from each other, the encapsulant 513 also protects the die 310 and bond wires 311 during the testing setup and the testing itself from, for example, physical damage and chemical contamination. Consequently, functional tests of the dies 310 that conventionally would have required the singulation of the sub-assemblies 530 may be performed concurrently. After the tape 440 is removed and the strip tests are performed, singulation is performed, where the assembly 550 is cut along cut lines (not shown) corresponding to the original plating busses 208 to form the below-described individual IC devices.

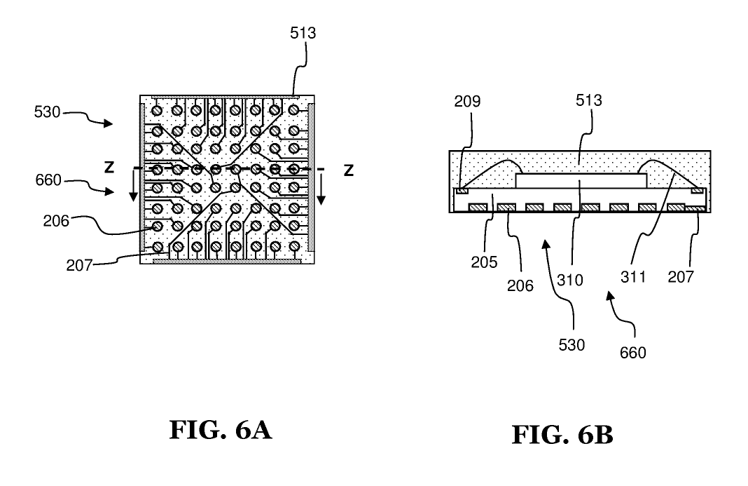

FIG. 6A is a bottom view of a singulated IC device 660 corresponding to a sub-assembly 530 of FIG. 5B. FIG. 6B is an enlarged side cross-sectional view of the IC device 660 of FIG. 6A along the cut line Z-Z. The sides of the IC device 660 are mostly made up of the encapsulant 513, which helps protect the components of the IC device 660 and, furthermore, covers up the sides of the electroplating traces 207, which in conventional BGA packages may be left exposed. Following the singulation step, conductive balls (not shown) may be attached to the bottom contact pads 206 using, for example, a soldering technique. Note that, alternatively, the conductive balls may be attached prior to singulation.

An embodiment of the invention has been described where the tape 440 is applied after wire bonding. The invention is not, however, so limited. In some alternative embodiments, the tape 440 is applied after the slot-forming and before the die attachment. In some alternative embodiments, the tape 440 is applied after the die attachment and before the wire bonding.

An embodiment of the invention has been described where the tape 440 covers the entirety of the substrate array 200. The invention is not, however, so limited. In some alternative embodiments, narrower tape bands are used that cover up at least the slots 221 and adjoining areas, so as to prevent leakage of the encapsulant onto and consequent contamination of the bottom contact pads 206, but that do not cover the entirety of the substrate array 200.

An embodiment of the invention has been described where the dies 310 are die-attached and wire-bonded to the individual substrates 201 to form wire-bonded BGA packages. The invention is not, however, so limited. In some alternative embodiments, dies are flip-chip attached and electrically connected to the corresponding individual substrates using conductive balls to generate flip-chip BGA packages. As would be appreciated by a person of skill in the art, the packaging of a flip-chip BGA package may include some variations, such as for example, (i) using different patterns for the top contact pads 209 and the vias/traces within the individual substrate 201 and (ii) using an underfill between the die and the individual substrate 201.

An embodiment of the invention has been described where the tape 440 is removed before the performance of the strip tests. The invention is not, however, so limited. In some alternative embodiments that use narrow tape which does not cover the bottom contact pads 206, the tape 440 does not need to be removed for electrical testing. In some other alternative embodiments, the strip-testing equipment may pierce through the tape 440 to contact the bottom contacts pads 206 with the tape 440 in place.

An embodiment of the invention has been described where each individual substrate 201 adjoins both other individual substrates 201 and the perimeter zone 202. The invention, however, is not so limited. In some alternative embodiments, some individual substrates adjoin only other individual substrates and do not adjoin the perimeter zone. In some alternative embodiments, some individual substrates adjoin only the perimeter zone and do not adjoin other individual substrates.

It will be further understood that various changes in the details, materials, and arrangements of the parts which have been described and illustrated in order to explain the nature of this invention may be made by those skilled in the art without departing from the scope of the invention as expressed in the following claims.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.” As used in this application, unless otherwise explicitly indicated, the term “connected” or “electrically connected” is intended to cover both direct and indirect connections between elements.

In this specification including any claims, the term “each” may be used to refer to one or more specified characteristics of a plurality of previously recited elements or steps. When used with the open-ended term “comprising,” the recitation of the term “each” does not exclude additional, unrecited elements or steps. Thus, it will be understood that an apparatus may have additional, unrecited elements and a method may have additional, unrecited steps, where the additional, unrecited elements or steps do not have the one or more specified characteristics.

Although the steps in the following method claims are recited in a particular sequence with corresponding labeling, unless the claim recitations otherwise imply a particular sequence for implementing some or all of those steps, those steps are not necessarily intended to be limited to being implemented in that particular sequence.

1. A method for packaging integrated circuit (IC) devices, the method comprising:
providing a substrate array comprising:
a top side;
a bottom side;
a plurality of individual substrates, wherein each individual substrate comprises a plurality of bottom contact pads and corresponding metal traces on the bottom side; and
plating busses located on the bottom side between adjoining substrates, and electrically connected to the bottom contact pads by way of the corresponding traces; and
forming slots in the substrate array by removing portions of the plating busses connected to the traces while leaving corner attachment zones connecting adjacent substrates.

2. The method of claim 1, wherein the providing step includes electroplating the bottom contact pads, the metal traces, and the plating busses.

3. The method of claim 1, wherein the substrate array further comprises:
a perimeter zone surrounding the plurality of individual substrates, and
wherein the plating busses are located on the bottom side between the perimeter zone and the plurality of individual substrates, and
the forming step includes forming slots between the perimeter zone and the plurality of individual substrates by removing portions of the plating busses connected to the traces while leaving corner attachment zones connecting the perimeter zone to the adjacent substrates.

4. The method of claim 1, wherein:
each individual substrate comprises, on the top side, a plurality of top contact pads and corresponding top metal traces;
the substrate array further comprises, on the top side, top plating busses located between adjoining substrates and electrically connected to the top contact pads by way of the top traces; and
the forming step includes removing portions of the top plating busses connected to the top traces.

5. The method of claim 4, wherein the substrate array further comprises:
a perimeter zone surrounding the plurality of individual substrates; and
top plating busses located on the top side between the perimeter zone and the plurality of individual substrates,
wherein the forming step includes forming slots between the plurality of individual substrates and the perimeter zone by removing portions of the top plating busses connected to the top traces while leaving corner attachment zones connecting the perimeter zone to the adjacent substrates.

6. The method of claim 1, further comprising:
attaching, on the top side, a plurality of dies to corresponding substrates; and
electrically connecting the dies to corresponding top contact pads on the top side of the corresponding substrate to form corresponding IC assemblies.

7. The method of claim 6, wherein the forming step electrically isolates the bottom contact pads to enable concurrent functional testing of the IC assemblies using the bottom contact pads.

8. The method of claim 6, further comprising performing concurrent functional testing of all of the IC assemblies.

9. The method of claim 6, further comprising:
attaching a removable tape to the bottom side to cover the slots; and
encapsulating the top side using an encapsulant, wherein:
the encapsulant fills the slots, and
the removable tape prevents leakage of the encapsulant onto the bottom contact pads.

10. The method of claim 9, further comprising performing concurrent functional testing of all of the IC assemblies.

11. The method of claim 10, further comprising singulating the IC assemblies to provide a plurality of corresponding separate IC devices, wherein the singulation includes removing the corner attachment zones.

12. A substrate array having a top side and a bottom side, the substrate array comprising:
an array of adjacent individual substrates, wherein:
each substrate comprises a plurality of bottom contact pads and corresponding conductive traces on the bottom side;
the substrates are separated from adjacent substrates by slots formed by removing a corresponding portion of a plating bus on the bottom side, the portion having been previously connected to the conductive traces;
the substrates are connected to one or more adjacent substrates by corner attachment zones comprising remains of the plating busses.

13. The substrate array of claim 12, wherein:
before removing the corresponding portions of the plating busses, the substrate array supported electroplating of the bottom contact pads by way of the corresponding traces and the plating busses; and
after removing the corresponding portions of the plating busses, the substrate array supports concurrent functional testing of IC devices mounted on the individual substrates and electrically connected to the bottom contact pads.

14. The substrate array of claim 12, further comprising:
a perimeter zone surrounding the plurality of individual substrates, wherein:
the perimeter zone is separated from each adjacent individual substrate by a slot formed by removing a corresponding portion of a plating bus on the bottom side, the portion having been previously connected to the traces of the adjacent individual substrate; and
the perimeter zone is connected to each adjacent individual substrate by corner attachment zones comprising remains of the plating busses.

15. The substrate array of claim 12, further comprising:
a plurality of dies on the top side, each die attached and electrically connected to a corresponding substrate; and
an encapsulant that covers the dies, and fills the slots.

16. The substrate array of claim 15, wherein the substrate array supports concurrent functional testing of the plurality of dies prior to separating the substrate-die assemblies from each other.

17. The substrate array of claim 15, wherein, after singulation of the substrate array-dies sub-assembly into singulated IC devices:
each singulated IC device comprises an individual substrate, the corresponding die, and a corresponding portion of the encapsulant; and
the corresponding portion of the encapsulant prevents exposure of portions of the traces of the singulated IC device.
